(19) United States
(12) Patent Application Publication
(10) Pub. No.: US 2015/0333297 A1
(43) Pub. Date: Nov. 19, 2015

(54) ORGANIC ELECTROLUMINESCENT DISPLAY DEVICE, METHOD FOR MANUFACTURING THE SAME AND DISPLAY APPARATUS

(71) Applicant: BOE Technology Group Co., Ltd., Beijing (CN)

(72) Inventors: Fei Liu, Beijing (CN); Xuan He, Beijing (CN); Qinghui Zeng, Beijing (CN); Hsieh-Ming Che, Beijing (CN)

(21) Appl. No.: 14/415,770

(22) PCT Filed: May 27, 2014
(86) PCT No.: PCT/CN2014/078536

§ 371 Date: Jan. 20, 2015

(30) Foreign Application Priority Data
Dec. 10, 2013 (CN) 201310674051.8

(51) Int. Cl. H01L 51/52; H01L 51/56; H01L 51/00

(52) U.S. Cl. CPC H01L 51/5293; H01L 51/5253; H01L 51/5262; H01L 51/0002; H01L 51/56; H01L 51/004; H01L 51/0034; H01L 51/0035; H01L 51/0048; H01L 2251/301; H01L 2251/303

(57) ABSTRACT

Disclosed is an organic electroluminescent display device, a manufacturing method thereof and a display apparatus including the same. The organic electroluminescent display device includes an substrate comprising a main material film layer, and a first phase difference film layer, a water and oxygen-proof film layer and a polarizing film layer provided to stack each other; an organic electroluminescent pixel array provided on the substrate, the organic electroluminescent pixel array may emitting visible light capable of passing through the substrate; and a package substrate or a package thin film cladding outside of the organic electroluminescent pixel array. The first phase difference film layer is located at a side of the polarizing film layer near the organic electroluminescent pixel array. The substrate may have the function of anti-reflection as well as the good performance of water-proof and oxygen-proof. In this way, the OLED device of bottom-emission type provided on the substrate may leave out double film-applying process for applying the circular polarizing filter and the water and oxygen-proof film layer, and avoid the problems of thickening the thickness of a flexible device and bending brought about by the double film-applying.

### BACKGROUND OF THE INVENTION

1. Field of the Invention

The present invention relates to an organic electroluminescent display device, a manufacturing method thereof and a display apparatus including the same.

2. Description of the Related Art

Currently, an organic electroluminescent display (OLED) device has been widely used in a display apparatus due to its characteristics of quick response, wide color gamut, ultrathin structure, and the capability of becoming flexible and the like as compared to a conventional liquid crystal display (LCD) device.

An OLED device mainly comprises a substrate, an organic electroluminescent pixel array provided on the substrate; wherein, each of the organic electroluminescent pixel array includes an anode and a cathode provided to be opposite to each other, and a luminescent layer between the anode and the cathode. Light is emitted from the OLED device by compounding an electron from the cathode and an electron hole from the anode in the luminescent layer and then energizing the organic material in the luminescent layer to emit light. However, in the OLED device, the organic material used as luminescent layer and an active material used as the cathode are both extremely susceptible to water and oxygen, thus, the OLED device needs much higher quality of package than other display device. Supposing that the OLED device is not securely packaged, water and oxygen will permeate into the display from the ambient environment to oxidize the metal of the cathode and deteriorate the organic material in the luminescent layer, thereby shortening the lifetime of the OLED device or directly causing fatal damages to the display device and thus causing work failure.

Presently, in the OLED device with small and middle sizes, the packaging is accomplished by glasses plate, while for the OLED device with large size or flexibility, the conventional method of packaging is to simply package the OLED device with a thin film firstly and then to apply a water and oxygen-proof protective film thereon. Moreover, for the sake of the reduction of displaying contrast ratio and visibility due to the reduction of environment light reflected by the OLED device and, a circular polarizing filter is applied after applying the water and oxygen-proof protective film. FIG. 1 is a schematic view of the structure of the OLED device in prior art, the OLED device comprises a substrate 1, an organic electroluminescent pixel array 2, a package thin film 3, a water and oxygen-proof protective film 4 and a circular polarizing filter 5.

It can be seen from the above-mentioned that the method for packaging the OLED device with large size or flexibility needs to apply films twice, which renders the process complicated and the increased cost. Moreover, double film-applying process will bring about the problem of thickening the thickness of a flexible device and the difficulty of bending.

### SUMMARY OF THE INVENTION

In view of this, embodiments of the present invention provide an organic electroluminescent display device, a manufacturing method thereof and a display apparatus including the same, the substrate has the function of anti-reflection as well as the good performance of water-proof and oxygen-proof and thus may simplify the manufacturing process and reduce the manufacturing cost.

According to the embodiment of one aspect of the present invention, there is provided an organic electroluminescent display device, comprising:
an substrate comprising a main material film layer, a first phase difference film layer, a water and oxygen-proof film layer and a polarizing film layer provided to stack each other;
an organic electroluminescent pixel array provided on the substrate, the organic electroluminescent pixel array emitting visible light capable of passing through the substrate; and
a package substrate or a package thin film cladding outside of the organic electroluminescent pixel array,
wherein, the first phase difference film layer is located at a side of the polarizing film layer near the organic electroluminescent pixel array.

In the OLED device according to the embodiments of the present invention, the substrate for carrying the organic electroluminescent pixel array utilizes multifunctional composite film layers, in detail, the substrate comprises: a main material film layer, and a first phase difference film layer, a water and oxygen-proof film layer and a polarizing film layer provided to stack each other; wherein, the combination of the first phase difference film layer and the polarizing film layer has a function of anti-reflection, and the water and oxygen-proof film layer has a performance of water-proof and oxygen-proof. Thus, the substrate has the function of anti-reflection as well as the good performance of water-proof and oxygen-proof. In this way, the OLED device of bottom-emission type provided on the substrate may leave out double film-applying process for applying the circular polarizing filter and the water and oxygen-proof film layer, and thus simplify the manufacturing process and reduce the manufacturing cost. What's more, this kind of OLED device also avoids the problem of thickening of the thickness of the flexible device and the difficulty of bending brought about by the double film-applying.

In the above-mentioned OLED device, the main material film layer is located at a side of the polarizing film layer far away from the first phase difference film layer.

In the above-mentioned OLED device, the water and oxygen-proof film layer is located at a side of the first phase difference film layer near the organic electroluminescent pixel array; and/or
between the first phase difference film layer and the polarizing film layer; and/or
between the polarizing film layer and the main material film layer.

In the above-mentioned OLED device, the substrate further comprises a second phase difference film layer located between the first phase difference film layer and the polarizing film layer.

In the above-mentioned OLED device, the second phase difference film layer is a half-wavelength phase difference film layer for the visible light.

In the above-mentioned OLED device, the first phase difference film layer is a quarter-wavelength phase difference film layer for the visible light.

In the above-mentioned OLED device, the main material film layer is made of any one of polyvinyl alcohol-based resin, polyethylene naphthalate-based resin, polyimide-based resin, polybutylene terephthalate-based plastic and phenol formaldehyde resin or the combination thereof.

In the above-mentioned OLED device, the water and oxygen-proof film layer is made of Al₂O₃, TiO₂, SiNx or SiC.

In the above-mentioned OLED device, the polarizing film layer is made of polyvinyl alcohol or carbon-nano tube.

According to the embodiments of another aspect of the present invention, there is also provided a method of manufacturing the above-mentioned organic electroluminescent display device, comprising steps of:
forming the substrate in the manner of roll to roll;
forming the organic electroluminescent pixel array on the substrate; and
forming the package substrate or the package thin film at the outside of the organic electroluminescent pixel array.

In the above-mentioned manufacturing method, the step of forming the substrate in the manner of roll to roll comprising:
unwinding the main material film layer and the first phase difference film layer winded on their respective scrolls at opposite sides of the polarizing film layer, respectively; and
by means of a pair of opposite rollers, bonding the main material film layer and the first phase difference film layer onto the polarizing film layer in the manner of rolling at opposite sides of the polarizing film layer, respectively.

In the above-mentioned manufacturing method, the step of forming the substrate in the manner of roll to roll comprising:
unwinding the main material film layer winded on a scroll at a side of the polarizing film layer; and
by means of a first pair of opposite rollers, bonding the polarizing film layer onto the main material film layer in the manner of rolling;
depositing the water and oxygen-proof film layer at another side of the polarizing film layer; and
unwinding the first phase difference film layer winded on a scroll at the side of the polarizing film layer deposited with the water and oxygen-proof film layer, and by means of a second pair of opposite rollers, bonding the first phase difference film layer onto the water and oxygen-proof film layer deposited on the polarizing film layer in the manner of rolling.

In the above-mentioned manufacturing method, the step of forming the substrate in the manner of roll to roll comprising:
unwinding the main material film layer and a second phase difference film layer winded on their respective scrolls at opposite sides of the polarizing film layer, respectively, and by means of a first pair of opposite rollers, bonding the main material film layer and the second phase difference film layer onto the polarizing film layer in the manner of rolling at opposite sides of the polarizing film layer, respectively;
depositing the water and oxygen-proof film layer on a side of the second phase difference film layer;
unwinding a first phase difference film layer winded on a scroll at the side of the second phase difference film layer deposited with the water and oxygen-proof film layer, and by means of a second pair of opposite rollers, bonding the first phase difference film layer onto the water and oxygen-proof film layer deposited on the second phase difference film layer in the manner of rolling.

In the above-mentioned manufacturing method, before bonding film layers onto the polarizing film layer, performing pretreatments of soaking and stretching the polarizing film layer.

According to the embodiments of further aspect of the present invention, there is also provided a display apparatus comprising the organic electroluminescent display device according to the embodiments of the present invention.

### BRIEF DESCRIPTION OF THE DRAWINGS

The above and other features of the present invention will become more apparent by describing in detail exemplary embodiments thereof with reference to the accompanying drawings, in which:

FIG. 1 is a schematic view of the structure of the OLED device in prior art;

FIG. 2a is a schematic structural view of the OLED device according to a first exemplary embodiment of the present invention;

FIG. 2b is a schematic structural view of the OLED device according to a second exemplary embodiment of the present invention;

FIG. 2c is a schematic structural view of the OLED device according to a third exemplary embodiment of the present invention;

FIG. 3a is a schematic principle view of manufacturing the substrate of FIG. 2a in the manner of roll to roll;

FIG. 3b is a schematic principle view of manufacturing the substrate of FIG. 2b in the manner of roll to roll; and

FIG. 3c is a schematic principle view of manufacturing the substrate of FIG. 2c in the manner of roll to roll.

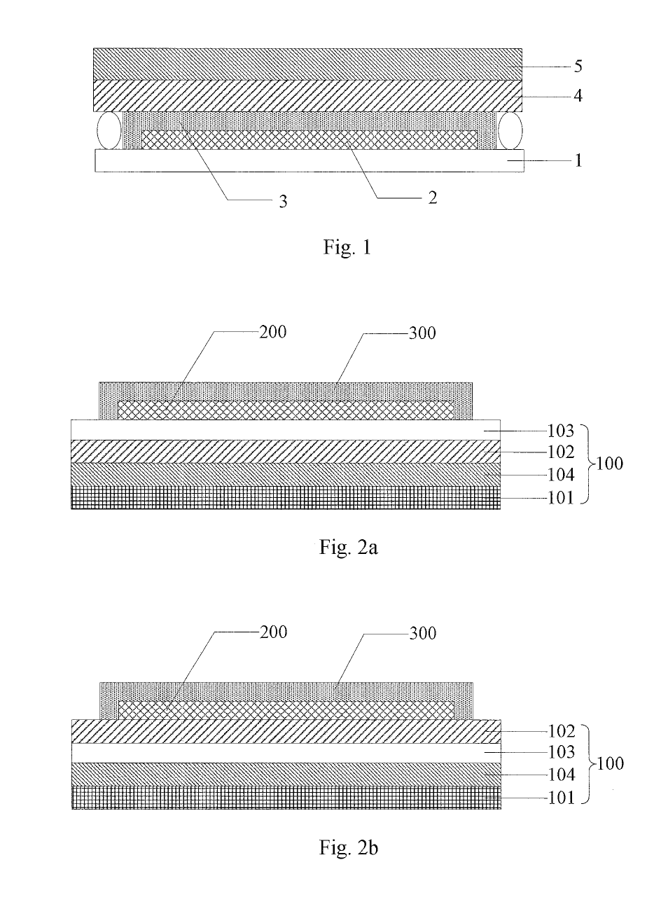

### DETAILED DESCRIPTION OF PREFERRED EMBODIMENTS OF THE INVENTION

In order to completely understand the technical solution of the present invention, exemplary embodiments of the present disclosure will be described hereinafter in detail with reference to the attached drawings. Obviously, the described embodiments are merely part of the embodiments of the present invention, rather than all of the embodiments of the present invention. Based on the embodiments of the present invention, other embodiments acquired by the person skilled in the art without any inventive effort will be within the protection scope of the present invention.

The thickness and size of each film layer in the attached drawings do not represent the real scale of the OLED device. Moreover, only partial structures of the OLED device are shown out and are intended to schematically illustrate the content of the present invention. In addition, in the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

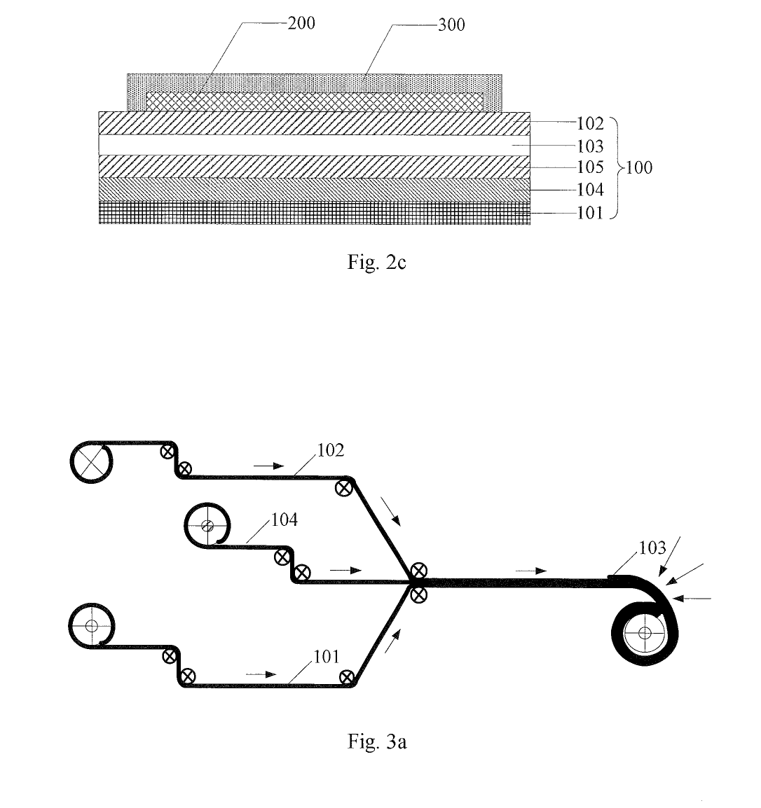

As shown in FIGS. 2a to 2c, the OLED device according to the exemplary embodiments of the present invention comprises: a substrate 100, an organic electroluminescent pixel array 200 provided on the substrate 100 and a package substrate or a package thin film 300 cladding outside of the organic electroluminescent pixel array 200. The organic electroluminescent pixel array 200 emits visible light capable of passing through the substrate 100, that's to say, the organic electroluminescent pixel array 200 of the present embodiment is of bottom emission type.

Further, the substrate 100 comprises: a main material film layer 101, a first phase difference film layer 102, a water and oxygen-proof film layer 103 and a polarizing film layer 104, which are provided to stack each other; wherein, the first phase difference film layer 102 is located at a side of the polarizing film layer 104 near the organic electroluminescent pixel array 200.

In the OLED device according to the embodiments of the present invention, the substrate for carrying the organic electroluminescent pixel array utilizes multifunctional composite film layers, in detail, the substrate comprises: the main material film layer, and the first phase difference film layer, the water and oxygen-proof film layer and the polarizing film layer which are provided on the main material film layer in the manner of stackping each other; wherein, the combination of the first phase difference film layer and the polarizing film layer have a function of anti-reflection, and the water and oxygen-proof film layer has a performance of water-proof and oxygen-proof. Thus, the substrate has the function of anti-reflection as well as the good performance of water-proof and oxygen-proof. In this way, the OLED device of bottom-emission type provided on the substrate may leave out double film-applying process for applying the circular polarizing filter and the water and oxygen-proof film layer, and thus simplify the manufacturing process and reduce production cost. What's more, this kind of OLED device also avoids the problem of thickening of the thickness of the flexible device and the difficulty of bending brought about by the double film-applying process.

Specifically, in the OLED device according to the embodiments of the present invention, the organic electroluminescent pixel array 200 may include a plurality of organic electroluminescent structures each consisting of an anode, an cathode and a luminescent layer between the anode and the cathode, and a plurality of thin film transistors each for controlling the respective organic electroluminescent structure. Specifically, the detailed structure of the organic electroluminescent pixel array 200 is the well-known prior art, and thus will not be described in detail herein.

In the OLED device according to the embodiments of the present invention, the combination of the first phase difference film layer 102 and the polarizing film layer 104 acts as a circular polarizing filter and have a main function of preventing the reflected light from passing therethrough.

Specifically, the main function of the polarizing film layer 104 is to transform the natural light passing through the polarizing film layer 104 into linearly polarized light, and the material for making the polarizing film layer 104 may be Polyvinyl Alcohol, for example.

In an exemplary embodiment, for example, the first phase difference film layer 102 is a quarter-wavelength phase difference film layer for the visible light, and has a main function of transforming the linearly polarized light passing through the first phase difference film layer 102 into circularly polarized light, or transforming circularly polarized light into linearly polarized light.

Thus, the first phase difference film layer 102 should be located at a side of the polarizing film layer 104 near the organic electroluminescent pixel array 200, that's to say, the polarizing film layer 104 is much closer to the external environment light than the first phase difference film layer 102. In this way, the natural light enters into the polarizing film layer 104, and after passing through the polarizing film layer 104, it is transformed into a first linearly polarized light, which is transformed into a left-handed circularly polarized light (or a right-handed circularly polarized light) after passing through the first phase difference film layer 102. The left-handed circularly polarized light (or the right-handed circularly polarized light) is changed into a right-handed circularly polarized light (or a left-handed circularly polarized light) after being reflected back by the organic electroluminescent pixel array 200, and then changed into a second linearly polarized light after passing through the first phase difference film layer 102 again. In this case, the second linearly polarized light is perpendicular to the first linearly polarized light and cannot pass through the linearly polarizing filter. In this way, the reflected light cannot pass through the polarizing film layer 104, therefore, the influence of the light from the external environment may be reduced and the contrast ratio may be improved.

In the OLED device according to an exemplary embodiment of the present invention, as shown in FIG. 2c, the composite film layers forming the substrate may also comprises: a second phase difference film layer 105 between the first phase difference film layer 102 and the polarizing film layer 104. The second phase difference film layer 105, for example, is a half-wavelength phase difference film layer for the visible light, and has a main function of delaying the light passing through the second phase difference film layer 105 by 762 phase. In this way, the polarizing function of the polarizing film layer 104 and the chrominance of the whole display device may be improved, thereby having a higher contrast ratio.

In the OLED device according to the embodiments of the present invention, as shown in FIGS. 2a to 2c, the main material film layer 101 acts as a supporting film layer and is located at a side of the polarizing film layer 104 far away from the first phase difference film layer 102, that's to say, the main material film layer 101 is the outermost film layer of the substrate 100. In this way, the main material film layer 101 having a certain hardness may protect the inside layers from being scratching. Certainly, the main material film layer 101 may be provided as a middle layer of the substrate 100, which will not be limited herein.

In an exemplary embodiment, the material forming the main material film layer 101 may be any one of polyvinyl alcohol-based resin, polyethylene naphthalate-based resin, polyimide-based resin, polybutylene terephthalate-based plastic and phenol formaldehyde resin and the like, or the combination thereof. These materials have poor water-proof performance, thus, the composite layers forming the substrate 100 also needs to provide with the water and oxygen-proof film layer 103.

In the OLED device according to the first exemplary embodiment of the present invention, as shown in FIG. 2a, the water and oxygen-proof film layer 103 may be located at a side of the first phase difference film layer 102 near the organic electroluminescent pixel array 200, that's to say, the organic electroluminescent pixel array 200 is brought into directly contact with the water and oxygen-proof film layer 103.

In the OLED device according to the second exemplary embodiment of the present invention, as shown in FIG. 2b, the water and oxygen-proof film layer 103 is provided between the first phase difference film layer 102 and the polarizing film layer 104. In a further alternative embodiment, the water and oxygen-proof film layer 103 is provided between the polarizing film layer 104 and the main material film layer 101, which will not be limited herein.

It should be note that the more the water and oxygen-proof film layer 103 closes to the outermost side of the substrate 100, i.e. the more the water and oxygen-proof film layer 103 is far away from the organic electroluminescent pixel array 200, the less the damage to the water and oxygen-proof film layer 103 is, when the organic electroluminescent pixel array 200 is manufactured on the substrate 100, thus, it prevents the water and oxygen-proof effect thereof from being impaired. Thus, in the design of the substrate 100, the water and oxygen-proof film layer 103 should be disposed to be far away from the organic electroluminescent pixel array 200 as much as possible.

In order to further protect the organic electroluminescent pixel array 200 from water and oxygen, in the OLED device according to the embodiments of the present invention, several water and oxygen-proof film layers 103 may be provided, that's to say, these water and oxygen-proof film layers 103 may be provided at three or any two or any one position of a side of the first phase difference film layer 102 near the organic electroluminescent pixel array 200, between the first phase difference film layer 102 and the polarizing film layer 104, or between the polarizing film layer 104 and the main material film layer 101. Furthermore, the materials of the water and oxygen-proof film layers 103 at various positions may be the same or different from each other, which will not be limited herein. In this way, it may achieve the multiple water and oxygen-proof effect of the organic electroluminescent pixel array, but at the same time it may thicken the whole thickness of the substrate. Thus, the number of the water and oxygen-proof film layer 103 may be determined based on actual requirement.

In an exemplary embodiment, the material forming the water and oxygen-proof film layer 103 generally may be inorganic compound, such as Al₂O₃, TiO₂, SiNx or SiC and the like, and the thickness of the water and oxygen-proof film layer 103 generally may be set within 10 nm-1 μm.

In an embodiment according to another aspect of the present invention, there is provided a method for manufacturing the OLED device, and comprises the following steps in detail:
forming an substrate in the manner of roll to roll;
forming an organic electroluminescent pixel array on the substrate; and
forming a package substrate or a package thin film at the outside of the organic electroluminescent pixel array.

The substrate 100 in the OLED device according to the embodiments of the present invention has composite layers, and is manufactured in the manner of roll to roll. The method for manufacturing the substrate will be described in detail, taking the substrates of FIG. 2a to FIG. 2c for instance.

### The First Embodiment

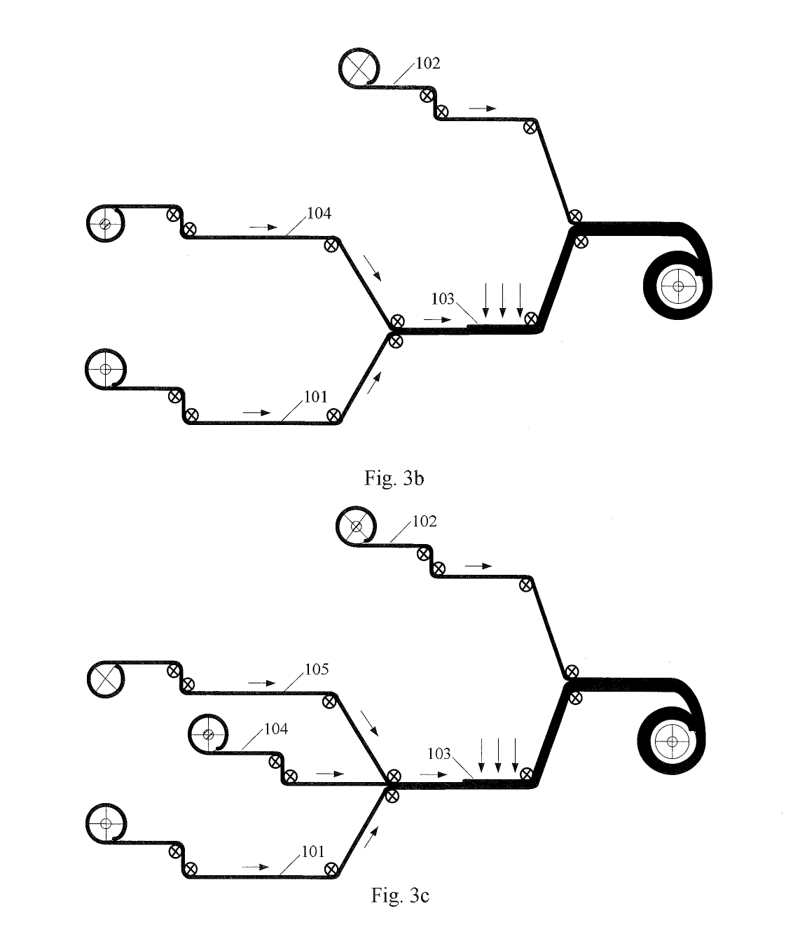

As shown in FIG. 3a, the method for manufacturing the substrate as shown in FIG. 2a in the manner of roll to roll comprises the following steps:
firstly, unwinding a polarizing film layer 104 winded on a scroll, performing pretreatments of soaking and stretching the polarizing film layer 104, unwinding a main material film layer 101 and a first phase difference film layer 102 winded on their respective scrolls at opposite sides of the polarizing film layer 104 after pretreatments, respectively, and by means of a pair of opposite rollers, bonding the main material film layer 101 and the first phase difference film layer 102 onto the polarizing film layer 104 in the manner of rolling at opposite sides of the polarizing film layer 104, respectively;
then, depositing a water and oxygen-proof film layer 103 on a side of the first phase difference film layer 102 so as to form a substrate 100;
finally, manufacturing an organic electroluminescent pixel array 200 on the substrate 100 by means of prior process, and packaging the organic electroluminescent pixel array 200.

### The Second Embodiment

As shown in FIG. 3b, the method for manufacturing the substrate as shown in FIG. 2b in the manner of roll to roll comprises the following steps:
firstly, unwinding the polarizing film layer 104 winded on a scroll, performing pretreatments of soaking and stretching the polarizing film layer 104, unwinding a main material film layer 101 winded on a scroll at a side of the polarizing film layer 104 after pretreatments, and by means of a first pair of opposite rollers, bonding the polarizing film layer 104 onto the main material film layer 101 in the manner of rolling;
then, depositing a water and oxygen-proof film layer 103 on the polarizing film layer 104 at the other side of the polarizing film layer 104;
then, unwinding a first phase difference film layer 102 winded on a scroll at a side of the polarizing film layer 104 deposited with the water and oxygen-proof film layer 103, and by means of a second pair of opposite rollers, bonding the first phase difference film layer 102 onto the water and oxygen-proof film layer 103 deposited on the polarizing film layer 104 in the manner of rolling so as to form a substrate 100;
finally, manufacturing an organic electroluminescent pixel array 200 on the substrate 100 by means of prior process, and packaging the organic electroluminescent pixel array 200.

### The Third Embodiment

As shown in FIG. 3c, the method for manufacturing the substrate as shown in FIG. 2c in the manner of roll to roll comprises the following steps:
firstly, unwinding a polarizing film layer 104 winded on a scroll, performing pretreatments of soaking and stretching the polarizing film layer 104, unwinding a main material film layer 101 and a second phase difference film layer 105 winded on their respective scrolls at opposite sides of the polarizing film layer 104 after pretreatments, respectively, and by means of a first pair of opposite rollers, bonding the main material film layer 101 and the second phase difference film layer 105 onto the polarizing film layer 104 in the manner of rolling at opposite sides of the polarizing film layer 104, respectively;
then, depositing a water and oxygen-proof film layer 103 on a side of the second phase difference film layer 105;
then, unwinding a first phase difference film layer 102 winded on a scroll at a side of the second phase difference film layer 105 deposited the water and oxygen-proof film layer 103, and by means of a second pair of opposite rollers, bonding the first phase difference film layer 102 onto the water and oxygen-proof film layer 103 deposited on the second phase difference film layer 105 in the manner of rolling so as to form a substrate 100;
finally, manufacturing an organic electroluminescent pixel array 200 on the substrate 100 by means of prior process, and packaging the organic electroluminescent pixel array 200.

In an embodiment according to a further aspect of the present invention, there is also provided a display apparatus, comprising an OLED device according to any one of the embodiments of the present invention. Since the problem-solving principle of this display apparatus is the same as that of the OLED device, the implementation of this display apparatus may refer to the implementation of the OLED device, in which the repetition will not be described again.

In the OLED device and the manufacturing method thereof and the display apparatus including the same according to the embodiments of the present invention, the substrate carrying an organic electroluminescent pixel array 200 utilizes a multifunctional composite film layers. In detail, the substrate comprises a main material film layer, a first phase difference film layer, a water and oxygen-proof film layer and a polarizing film layer, which are provided to stack each other, wherein, the combination of the first phase difference film layer and the polarizing film layer has a function of anti-reflection, and the water and oxygen-proof film layer has a performance of water-proof and oxygen-proof. In this way, the OLED device of bottom-emission type provided on the substrate may leave out double film-applying process for applying the circular polarizing filter and the water and oxygen-proof film layer, and thus simplify the manufacturing process and reduce production cost. What's more, this kind of OLED device also avoids the problem of thickening of the thickness of the flexible device and the difficulty of bending brought about by the double film-applying.

It is obvious for the person skilled in the art that various changes or modifications may be made in these embodiments without departing from the principles and spirit of the disclosure. In this way, supposing that these changes or modification to the present invention are within the claims and their equivalents, the present invention intends to include these changes or modification therein.

1. An organic electroluminescent display device, comprising:
an substrate comprising a main material film layer, a first phase difference film layer, a water and oxygen-proof film layer and a polarizing film layer provided to stack each other;
an organic electroluminescent pixel array provided on the substrate, the organic electroluminescent pixel array emitting visible light capable of passing through the substrate; and
a package substrate or a package thin film cladding outside of the organic electroluminescent pixel array,
wherein, the first phase difference film layer is located at a side of the polarizing film layer near the organic electroluminescent pixel array.

2. The display device according to claim 1, wherein, the main material film layer is located at a side of the polarizing film layer far away from the first phase difference film layer.

3. The display device according to claim 2, wherein, the water and oxygen-proof film layer is located
at a side of the first phase difference film layer near the organic electroluminescent pixel array, and/or
between the first phase difference film layer and the polarizing film layer, and/or
between the polarizing film layer and the main material film layer.

4. The display device according to claim 1, wherein, the substrate further comprises a second phase difference film layer located between the first phase difference film layer and the polarizing film layer.

5. The display device according to claim 4, wherein, the second phase difference film layer is a half-wavelength phase difference film layer for the visible light.

6. The display device according to claim 1, wherein, the first phase difference film layer is a quarter-wavelength phase difference film layer for the visible light.

7. The display device according to claim 1, wherein, the main material film layer is made of any one of polyvinyl alcohol-based resin, polyethylene naphthalate-based resin, polyimide-based resin, polybutylene terephthalate-based plastic and phenol formaldehyde resin, or the combination thereof.

8. The display device according to claim 1, wherein, the water and oxygen-proof film layer is made of Al₂O₃, TiO₂, SiNx or SiC.

9. The display device according to claim 1, wherein, the polarizing film layer is made of polyvinyl alcohol or carbon-nano tube.

10. A method of manufacturing the organic electroluminescent display device, the organic electroluminescent device comprising:
a substrate comprising a main material film layer, a first phase difference film layer, a water and oxygen-proof film layer and a polarizing film layer provided to stack each other;
an organic electroluminescent pixel array provided on the substrate, the organic electroluminescent pixel array emitting visible light capable of passing through the substrate; and
a package substrate or a package thin film cladding outside of the organic electroluminescent pixel array,
wherein, the first phase difference film layer is located at a side of the polarizing film layer near the organic electroluminescent pixel array,
the method comprising steps of:
forming the substrate in the manner of roll to roll;
forming the organic electroluminescent pixel array on the substrate; and
forming the package substrate or the package thin film at the outside of the organic electroluminescent pixel array.

11. The method according to claim 10, wherein, the step of forming the substrate in the manner of roll to roll comprising:
unwinding the main material film layer and the first phase difference film layer winded on their respective scrolls at opposite sides of the polarizing film layer, respectively; and
by means of a pair of opposite rollers, bonding the main material film layer and the first phase difference film layer onto the polarizing film layer in the manner of rolling at opposite sides of the polarizing film layer, respectively.

12. The method according to claim 10, wherein, the step of forming the substrate in the manner of roll to roll comprising:
unwinding the main material film layer winded on a scroll at a side of the polarizing film layer; and
by means of a first pair of opposite rollers, bonding the polarizing film layer onto the main material film layer in the manner of rolling;
depositing the water and oxygen-proof film layer at another side of the polarizing film layer; and
unwinding the first phase difference film layer winded on a scroll at the side of the polarizing film layer deposited with the water and oxygen-proof film layer, and by means of a second pair of opposite rollers, bonding the first phase difference film layer onto the water and oxygen-proof film layer deposited on the polarizing film layer in the manner of rolling.

13. The method according to claim 10, wherein, the step of forming the substrate in the manner of roll to roll comprising:
unwinding the main material film layer and a second phase difference film layer winded on their respective scrolls at opposite sides of the polarizing film layer, respectively, and by means of a first pair of opposite rollers, bonding the main material film layer and the second phase difference film layer onto the polarizing film layer in the manner of rolling at opposite sides of the polarizing film layer, respectively;
depositing the water and oxygen-proof film layer on a side of the second phase difference film layer;
unwinding the first phase difference film layer winded on a scroll at the side of the second phase difference film layer deposited with the water and oxygen-proof film layer, and by means of a second pair of opposite rollers, bonding the first phase difference film layer onto the water and oxygen-proof film layer deposited on the second phase difference film layer in the manner of rolling.

14. The method according to claim 11, wherein, before bonding film layers onto the polarizing film layer, performing pretreatments of soaking and stretching the polarizing film layer.

15. A display apparatus, comprising the organic electroluminescent display device according to claim 1.

16. The method according to claim 12, wherein, before bonding film layers onto the polarizing film layer, performing pretreatments of soaking and stretching the polarizing film layer.

17. The method according to claim 13, wherein, before bonding film layers onto the polarizing film layer, performing pretreatments of soaking and stretching the polarizing film layer.
